(19) United States
(12) Patent Application Publication
(10) Pub. No.: US 2005/0253598 A1
(43) Pub. Date: Nov. 17, 2005

(54) Capacitance detection-type sensor

(75) Inventor: Ken Kawahata, Tokyo (JP)

Correspondence Address: Beyer Weaver & Thomas, LLP, P.O. Box 778, Berkeley, CA, 94704-0778, US

(73) Assignee: ALPS ELECTRIC CO., LTD.

(21) Appl. No.: 11/107,669

(22) Filed: Apr. 14, 2005

(30) Foreign Application Priority Data
May 12, 2004 (JP) 2004-142283

(51) Int. Cl. G01R 27/26

(52) U.S. Cl. 324/671

(57) ABSTRACT

A capacitance detection-type sensor detects an electrostatic capacitance between a subject to be detected and a detection electrode arranged on a surface of the sensor and detects the shape of the subject to be detected. The capacitance detection-type sensor includes a reference electrode that is arranged near the detection electrode and detects a potential of the subject to be detected and a potential detecting section that measures a detection potential based on the electrostatic capacitance of the detection electrode with the potential as a reference potential.

### BACKGROUND OF THE INVENTION

1. Field of the Invention

The present invention relates to a capacitance detection-type sensor suitable for detecting an unevenness of a subject to be detected such as a fingerprint or the like.

2. Description of the Related Art

Conventionally, capacitance detection-type sensors which detect an unevenness of a subject to be detected have been known. In the capacitance detection-type sensor, column wiring lines and row wiring lines, which are made of transparent electrodes, are formed on a glass substrate. Then, a capacitance between the wiring lines (a detecting capacitive element at an intersection portion of the wiring lines) is detected and a change in capacitance is measured by a peripheral circuit.

In the capacitance detection-type sensor, as the peripheral circuit that performs the capacitance detection, for example, a charge amplifier circuit shown in FIG. 9 is favorably used (for example, see Japanese Unexamined Patent Application Publication No. 2001-46359).

When there is no influence by a noise from an exterior, the charge amplifier circuit is not influenced by a parasitic capacitance on the row wiring lines that transfers signals to the peripheral circuit. The charge amplifier circuit has a function of converting the change in capacitance into a voltage value.

On the other hand, when the charge amplifier circuit is influenced by a noise from the subject to be detected, the noise inputted from the subject to be detected is inputted from all detecting capacitive elements which are formed with the row wiring lines connected to the charge amplifier circuit. Accordingly, an output voltage Vo of the charge amplifier circuit has a voltage value which is represented by the following equation (1).
Vo=−CxVi/Cf−CnVn/Cf (1)

Here, Vi is an input voltage, Vn is a voltage value of the noise to be inputted, Cx is a capacitance of a selected detecting capacitive element, Cn is a value of a parasitic capacitance, and Cf is a value of a feedback capacitance in the charge amplifier circuit.

To the contrary, as for a method of reducing the influence by the noise inputted from the subject to be detected, a method in which the subject to be detected is reliably grounded so as to effectively reduce the noise has been considered.

For example, as a countermeasure against static electricity to protect a capacitance detection element from an electrostatic breakdown, a method in which a ground electrode 106 is formed around a detection electrode 105 on a surface of a capacitance detection-type sensor 105a (see FIG. 10) has been suggested (for example, see Japanese Unexamined Patent Application Publication No. 2001-324303).

It has been considered that the above-described configuration of the countermeasure against static electricity also has an advantage in that the influence by the noise inputted from the subject to be detected is reduced.

In the capacitance detection-type sensor disclosed in Japanese Unexamined Patent Application Publication No. 2001-46359, a number of capacitance detection elements are connected to the column wiring lines which transfer a current corresponding to the change in capacitance to a detection circuit. Accordingly, the parasitic capacitance Cn, which is typically considered, is hundreds times as large as the capacitance Cx of one capacitance detection element to be actually measured. Then, if the sensitivity of the charge amplifier circuit is increased so as to detect a minute change in capacitance, an amplifier at a first stage of the output of the charge amplifier circuit is saturated due to the voltage according to the change in capacitance based on the noise from the subject to be detected. As a result, there is a problem in that the capacitance of the capacitance detection element to be measured cannot be measured.

Further, in the capacitance detection-type sensor disclosed in Japanese Unexamined Patent Application Publication No. 2001-324303, as shown in the drawings, the noise from the subject to be detected cannot be grounded up to a level close to ‘0’ due to the limited ground area.

### SUMMARY OF THE INVENTION

The invention has been made in consideration of the above-described problems, and it is an object of the invention to provide a capacitance detection-type sensor which favorably detects a shape without being influenced by a noise from a subject to be detected.

According to an aspect of the invention, there is provided a capacitance detection-type sensor which detects an electrostatic capacitance between a subject to be detected and a detection electrode arranged on a surface of the sensor and detects the shape of the subject to be detected. The capacitance detection-type sensor has a reference electrode that is arranged around the detection electrode to detect a potential of the subject to be detected and a potential detecting section that measures a detection potential based on the electrostatic capacitance of the detection electrode with the potential as a reference potential.

In the capacitance detection-type sensor according to the aspect of the invention, the reference electrode is arranged around the detection electrode. Then, when the voltage due to the noise inputted from the subject to be detected is set to the reference voltage, the difference between the measurement voltage measured by the detection electrode and the reference voltage is calculated. Thus, substantially, an influence by a noise voltage superimposed on the measurement voltage can be reduced and a saturation of an amplifier at a first stage of a charge amplifier can be reduced. As a result, a voltage by the electrostatic capacitance between the subject to be detected and the detection electrode can be measured with high precision.

In the aspect of the invention, the capacitance detection-type sensor may be configured such that row wiring lines and column wiring lines are arranged on a substrate in a matrix shape and a change in capacitance between both wiring lines is detected at intersections of the row wiring lines and the column wiring lines.

The capacitance detection-type sensor in which the row wiring lines and the column wiring lines cross each other to form measuring capacitive elements generally may have the capacitance detection elements at the intersections of the column wiring lines and the row wiring lines. For example, when the column wiring lines are used to supply driving pulses to detect the capacitance, the row wiring lines transfer a current generated by the above-described pulses to the detection circuit. However, in the measurement, the measuring capacitive elements which are not driven are connected to the row wiring lines as the parasitic capacitance. Accordingly, the value of the parasitic capacitance becomes extremely large and the influence by the noise becomes severe.

Therefore, in the capacitance detection-type sensor 5 of aspect of the invention, the difference between the measurement voltage and the reference voltage is calculated. Thus, even when the noise voltage is superimposed on the measurement voltage, similarly, the difference is calculated by the voltage to be superimposed. Thus, with respect to the above-described sensor, in particular, the influence by the noise can be reduced and the saturation of the amplifier at the first stage of the charge amplifier can be reduced. As a result, the voltage by the electrostatic capacitance between the subject to be detected and the detection electrode can be measured with high precision.

In the capacitance detection-type sensor of the aspect of invention, it is preferable that a ground electrode is arranged near the detection electrode.

For this reason, in the capacitance detection-type sensor of the aspect of the invention, the noise from the subject to be detected is absorbed by the neighboring ground electrode to some degree. Thus, a superimposition level of the noise on the detection electrode can be lowered and the reference voltage for acquiring the difference at the first stage of the charge amplifier can be suppressed to a low voltage. As a result, the saturation of the amplifier at the first stage of the charge amplifier can be more lowered, and thus the measurement can be performed with high precision.

In the capacitance detection-type sensor of the aspect of the invention, it is preferable that the potential detecting section acquires the difference between the detection potential by the detection electrode that detects the potential of the subject to be detected and the detection potential of another detection electrode adjacent to the detection electrode and outputs the difference as the detection potential of the measurement result.

For this reason, in the capacitance detection-type sensor of the aspect of the invention, the difference between adjacent row wiring lines is acquired. Thus, it has an advantage in that noise components (having almost the same phase between the wiring lines) which are not eliminated at the time when the difference from the reference voltage is acquired are favorably eliminated with respect to the above-described configuration.

In the capacitance detection-type sensor of the aspect of the invention, it is preferable that the reference electrode and the ground electrode is formed in a comb-teeth shape and the detection electrode is formed between the comb tooth of each of the reference electrode and the ground electrode.

For this reason, in the capacitance detection-type sensor of the aspect of the invention, the reference electrode and the ground electrode can be arranged near the detection electrode. Thus, the noise can be absorbed by the neighboring detection electrode and a change in voltage of the noise that influences on each of the detection electrode and the reference electrode has the same shape. That is, the noise superimposed on the detection voltage corresponds to the reference voltage. Therefore, the superimposition level of the noise on the detection electrode can be lowered and the reference voltage for acquiring the difference at the first stage of the charge amplifier can be suppressed to the low voltage. Further, the saturation of the amplifier at the first stage of the charge amplifier can be more lowered and the measurement can be performed with high precision.

### BRIEF DESCRIPTION OF THE DRAWINGS

FIG. 1 is a plan view showing an example of a configuration of a capacitance detection-type sensor according to an embodiment of the invention;

FIG. 2 is a conceptual diagram showing a cross-sectional structure of the capacitance detection-type sensor taken along the line 2-2 of FIG. 1;

FIG. 3 is a detail view showing a structure of a portion of a detection electrode 1 in the capacitance detection-type sensor of FIG. 1;

FIG. 4 is a cross-sectional view showing a cross-sectional structure of the portion of the detection electrode 1 taken along the line 4-4 of FIG. 3;

FIG. 5 is a conceptual diagram showing an example of configuration of a charge amplifier circuit 11 which is used for the invention; and

FIG. 6 is a conceptual diagram showing a configuration of a charge amplifier circuit in a second embodiment of the invention;

FIG. 7 is a conceptual diagram showing a configuration of a charge amplifier circuit in a third embodiment of the invention;

FIG. 8 is a plan view showing a planar structure of a capacitance detection-type sensor according to a fourth embodiment of the invention;

FIG. 9 is a conceptual diagram showing a configuration of a charge amplifier which is used for a capacitance detection-type sensor according to a related art; and

FIG. 10 is a plan view showing a planar structure of the capacitance detection-type sensor according to the related art.

### DESCRIPTION OF THE PREFERRED EMBODIMENT

A capacitance detection-type sensor of an aspect of the invention detects electrostatic capacitance between a subject to be detected and a detection electrode arranged on a surface of the sensor and detects the shape of the subject to be detected. The capacitance detection-type sensor includes a reference electrode that is arranged near the detection electrode and detects a potential of the subject to be detected and a potential detecting section that measures a detection potential based on the electrostatic capacitance on the detection electrode with the potential as a reference potential.

Further, the capacitance detection-type sensor is configured such that row wiring lines and column wiring lines are arranged on a substrate in a matrix shape and unevenness of the subject to be detected is detected by a change in capacitance between both wiring lines at intersections of the row wiring lines and the column wiring lines.

### First Embodiment

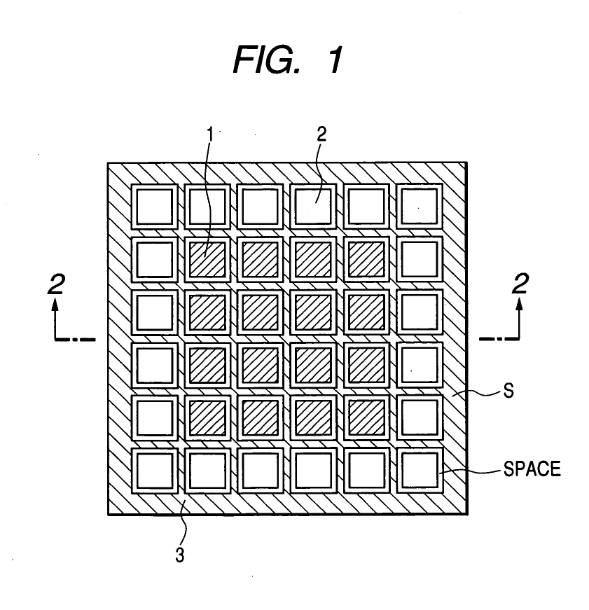

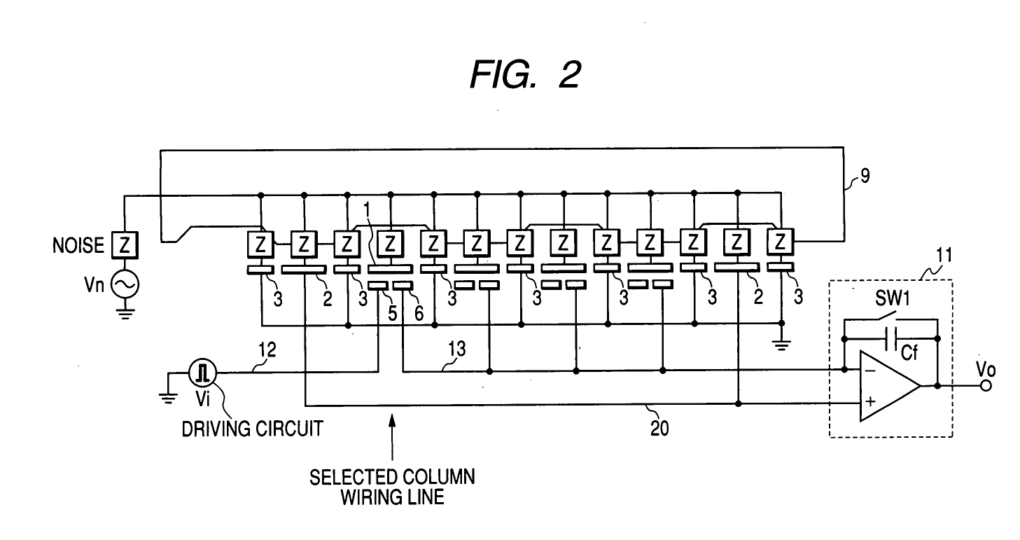

Hereinafter, a capacitance detection-type sensor according to a first embodiment of the invention will be described with reference to the drawings. FIG. 1 is a conceptual diagram showing an example of a configuration of the first embodiment in a plan view. FIG. 2 is a conceptual diagram showing a cross-section taken along the line 2-2 of FIG. 1.

Referring to FIGS. 1 and 2, a detection section S is provided with n×m (where n and m are natural numbers) detection electrodes 1 at a predetermined pitch, for example, at a pitch of 50 μm.

Around the detection section S, a plurality of reference electrodes 2 are provided at the same pitch as that of the detection electrodes 1 (here, the reference electrodes 2 are provided in a single line in all directions of the detection section S, but plural lines of the reference electrodes 2 may be provided).

Further, the detection electrodes 1 and the reference electrodes 2 are respectively surrounded by a ground electrode 3 having predetermined spaces (the ground electrode 3 is spatially isolated from the detection electrodes 1 and the reference electrodes 2 such that the ground electrode 3 is not electrically connected thereto).

Hereinafter, an operation which eliminates an influence by noise in the capacitance detection-type sensor according to the first embodiment of the invention will be described with reference to FIGS. 1 and 2.

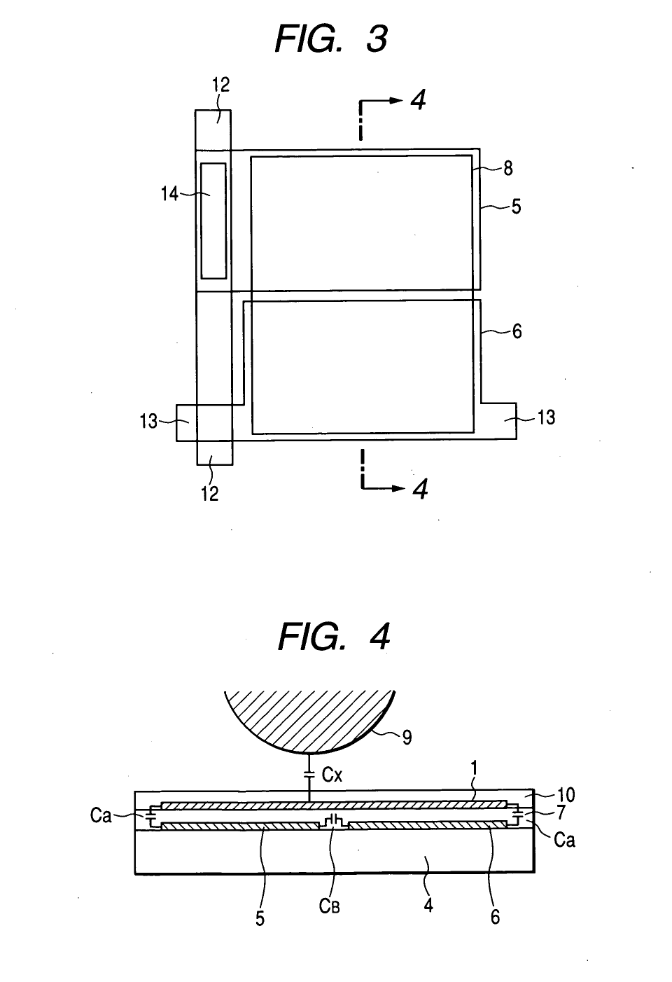

Here, the capacitance detection-type sensor of the first embodiment of the invention is an example of a capacitance detection-type sensor which operates according to control signals applied from an exterior to column wiring lines and row wiring lines, without having switching elements such as transistors. FIG. 3 is an expanded view of a portion of the detection electrode 1 of FIG. 1. FIG. 4 is a cross-sectional view taken along the line 4-4 of FIG. 3. As shown in FIGS. 3 and 4, the capacitance detection-type sensor has the row wiring lines 13 and the column wiring lines 12 that are arranged in a matrix shape on an active substrate 4. Further, at intersections of the row wiring lines 13 and the column wiring lines 12, the capacitance detection-type sensor has driving electrodes 5 which extend from the column wiring lines 12, sensing electrodes 6 which are arranged in pairs with the driving electrodes 5 and extend from the row wiring lines 13 adjacent to the driving electrodes 5, and the floating detection electrodes 1 that are arranged above the driving electrodes 5 and the sensing electrodes 6 with an interlayer insulating film 7 interposed therebetween. The capacitance detection-type sensor of the first embodiment of the invention detects a displacement current which flows from the driving electrode 5 to the sensing electrode 6. In this case, the displacement current is changed the distance between the subject to be detected 9 and the detection electrode 1.

Here, as shown in FIG. 3, the driving electrode 5 and the sensing electrode 6 are formed to overlap the detection electrode 1. That is, the driving electrode 5 and the sensing electrode 6 are capacitive-coupled with the detection electrode 1. In addition, the displacement current flows from the driving electrode 5 to the sensing electrode 6 via the detection electrode 1.

Further, on an upper surface of the detection electrode 1, a passivation film 10 may be formed to protect the detection electrode 1.

Returning to FIG. 2, if a detection pulse is outputted from a driving circuit to the driving electrode 5, when the subject to be detected, for example, a finger 9 is spaced by a sufficient distance from the detection electrode 1 (the finger 9 does not come in contact with the detection electrode 1 or a curve of the finger 9 corresponds to the detection electrode 1), the capacitance Cx between the detection electrode 1 and the finger 9 is very small. Thus, the displacement current corresponding to the voltage of the detection pulse applied to the driving electrode 5 flows in the sensing electrode 6 via the detection electrode 1. Here, symbol Z in FIG. 2 denotes predetermined impedance.

On the other hand, for example, when the finger 9 is near the detection electrode 1 (the ridge of the finger 9 corresponds to the detection electrode 1), the capacitance Cx between the detection electrode 1 and the finger 9 has an unnegligible value (shielded by a potential of the human body). Then, the displacement current corresponding to the voltage of the driving pulse applied to the driving electrode 5 flows in both of the finger 9 and the sensing electrode 6 via the detection electrode 1. Thus, the displacement current flowing in the sensing electrode 6 is reduced.

As such, according to the distance between the curve and the ridge of the finger 9, the degree of coupling between the driving electrode 5 and the sensing electrode 6 is changed in an analog manner and the displacement current is changed accordingly. Thus, by detecting the change amount, the degree of unevenness of the fingerprint is detected.

Here, the row wiring line 13 is connected to an inverted terminal of the charge amplifier 11 (the potential detecting section having an operational amplifier) and the displacement current flowing in the sensing electrode 6 is supplied corresponding to the voltage Vi of the driving pulse that is applied to the driving electrode 5. The charge amplifier 11 is a current/voltage conversion circuit and converts the displacement current flowing therein into the detection voltage (the detection potential) according to the value of the capacitance.

The capacitance Cf is the feedback capacitance and is provided parallel to a switch SW1 between the inversion terminal (−) and an output terminal.

At this time, for example, the human body serving as an antenna receives electromagnetic waves (emitted from a fluorescent lamp or the like) from a periphery. Then, the noise voltage Vn from the finger 9 is applied to the detection electrode 1 and a noise current is superimposed on the displacement current. Accordingly, the displacement current including the noise current is supplied to the inversion terminal (−).

Around the detection electrode 1, the ground electrode 3 is provided. Then, the finger 9 comes in contact with the ground electrode 3, as well as the detection electrode 1, such that a change in potential of the human body is suppressed based on the electromagnetic waves of the periphery.

Further, as described above, around the detection electrodes 1, the reference electrodes 2 are arranged. Thus, when the finger 9 comes in contact with the detection electrode 1, the finger 9 simultaneously comes in contact with the reference electrode 2 as well as the ground electrode 3.

Here, when the finger 9 comes in contact with the detection electrode 1, the finger 9 has to come in contact with the reference electrode 2. Accordingly, as regards positional relationship between the detection electrodes 1 and the reference electrodes 2, the reference electrodes 2 need to be arranged near (adjacent to) the detection electrodes 1.

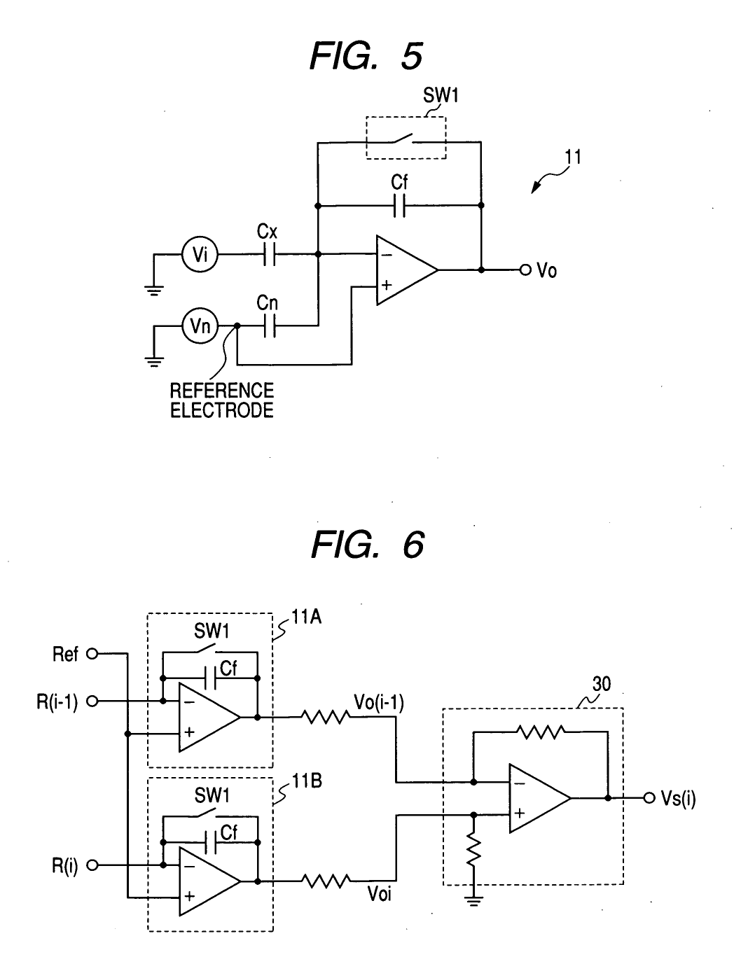

For this reason, in the present embodiment, the reference electrode 2 is formed to have the surface shape as that of the detection electrode 1. Further, as shown in FIG. 5, the reference electrode 2 is connected to a non-inversion terminal (+) of the charge amplifier 11 via an internal wiring line 20.

Here, the switch SW1 is turned on before the start of the measurement to discharge the electric charges stored in the capacitance Cf and is turned off during the measurement.

Further, the input voltage (the detection voltage) Vi is inputted to the inversion terminal (−) of the charge amplifier circuit 11 via the capacitance Cx. In addition, the reference voltage Vn is inputted to the non-inversion terminal (+) of the charge amplifier circuit 11 via the capacitance Cn.

According to this configuration, the output (Vo) of the charge amplifier is represented by the following equation (2).
Vo=−CxVi/Cf+(1+Cx/Cf)Vn (2)
Here, Vi is the input voltage (the detection voltage based on the displacement current), Vn is a voltage value of the noise to be inputted, Cx is a capacitance of a selected detecting capacitive element, Cn is a value of the parasitic capacitance, and Cf is a value of the feedback capacitance in the charge amplifier circuit.

As described above, if the noise voltage Vn is applied to the non-inversion terminal of the charge amplifier circuit 11, the noise voltage Vn inputted to the inversion terminal from the parasitic capacitance Cn after being superimposed on the displacement current can be cancelled. Thus, as compared to the related art, the amplification of the noise voltage Vn can be drastically suppressed.

Therefore, when the charge amplifier circuit 11 operates with a predetermined power supply voltage, the charge amplifier circuit 11 can be prevented from being saturated due to the drastic amplification of the noise voltage Vn. As a result, a dynamic range for measuring the input voltage Vi can be enlarged and the measurement can be performed with high precision.

### Second Embodiment

Further, in a second embodiment, the sensor itself has the same configuration as that of the first embodiment. The second embodiment is different from the second embodiment in that a circuit for removing the noise voltage of each subject to be measured superimposed on the voltage of the row wiring line is provided at the back of the charge amplifier circuit 11.

That is, as shown in FIG. 6, the second embodiment is configured such that, in adjacent (or neighboring) row wiring lines R(i) and R(i−1), the difference between the voltage V(i) of the row wiring R(i) and the voltage V(i−1) of the row wiring line R(i−1) is acquired.

Here, a charge amplifier circuit 11A, an output voltage Vo(i−1) is outputted according to the equation (2) based on the input voltage V(i−1) of the row wiring line R(i−1) and the reference voltage Vn.

Further, similarly, in a charge amplifier circuit 11B, an output voltage Vo(i) is outputted according to the equation (2) based on the input voltage V(i) of the row wiring line R(i) and the reference voltage Vn.

Then, the output voltage Vo(i) is inputted to a non-inversion terminal of an operational amplifier 30 and the output voltage Vo(i−1) is inputted to an inversion terminal of the operational amplifier 30.

That is, in the circuit shown in FIG. 6, the difference between the output voltage Vo(i) and the output voltage Vo(i−1) is acquired. Here, in order to calculate a differential voltage Vs(i) which represents the difference, the following subtraction is performed.
Vs(i)=V(i)−V(i−1) (where 1≦i≦N and N is the number of the row wiring lines)
Here, R(0) is a dummy row wiring line to which a predetermined voltage is applied, that is, a reference row wiring line.

Similarly to other row wiring lines, the noise is also inputted to the reference row wiring line R(0) and the differential voltage Vs(0) is a voltage in which the noise is superimposed on the predetermined voltage.

Therefore, since the difference of the voltage for adjacent row wiring lines is acquired, the noise component superimposed on the input voltage of the row wiring line to be measured is removed. Then, the second term regarding the noise at the right side in the equation (2) is cancelled and thus the noise component is completely removed by the operational amplifier 30.

The measurement result of the differential voltage Vs is as follows.
Vs(1)=V(1)−V(0)
Vs(2)=V(2)−V(1)
Vs(i)=V(i)−V(i−1)
That is, the difference in measurement voltage between adjacent row wiring lines are sequentially subtracted to calculate the differential voltage Vs for adjacent row wiring lines.

Next, the sequentially acquired differences are added to calculate a displacement voltage of the voltage as the measurement voltage of each row wiring line with the differential voltage Vs(1) of the row wiring line R(1) as a reference.

Measurement Voltage of Wiring Line R(1):
Differential Voltage Vs(1)

Measurement Voltage of Wiring Line R(2):
Differential Voltage Vs(1)+Vs(2)

Measurement Voltage of Wiring Line R(i):
Differential Voltage Vs(1)+Vs(2)++Vs(i)
   That is, the differential voltage corresponding to each row wiring line is sequentially added (that is, integral) to the differential voltage of the row wiring line (the first wiring line) as the difference from that of the reference row wiring line. With the differential voltage Vs(1) of the first row wiring line as a reference, the change in voltage of the measurement voltage of each row wiring line can be acquired. Based on the change in voltage, the state of the unevenness of the subject to be measured can be detected.

### Third Embodiment

In the measurement, another example of the configuration of the charge amplifier circuit 11 (11A and 11B) will be described as a third embodiment.

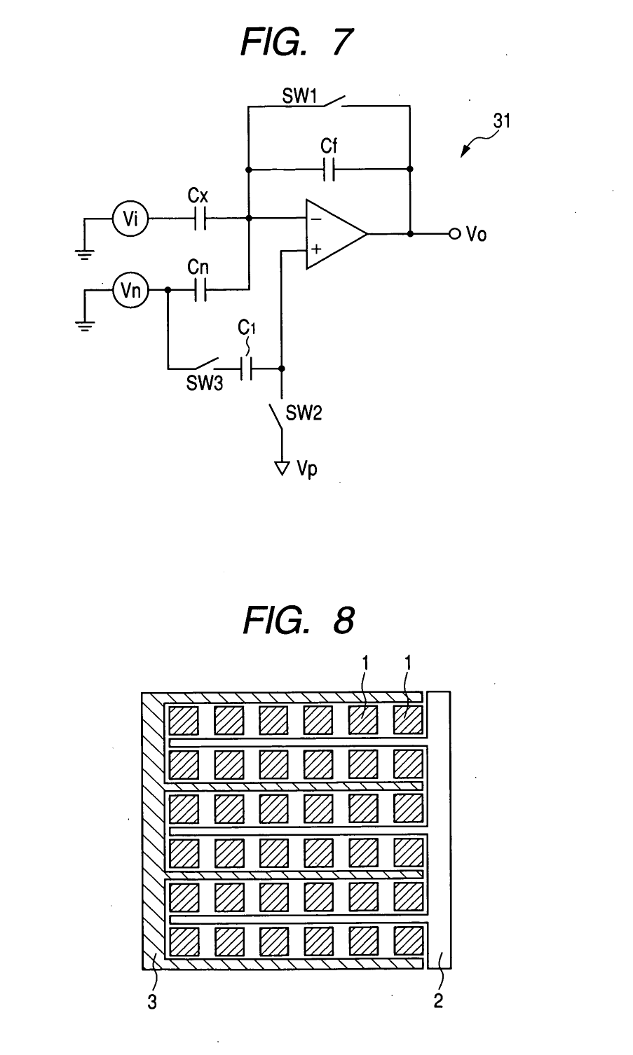

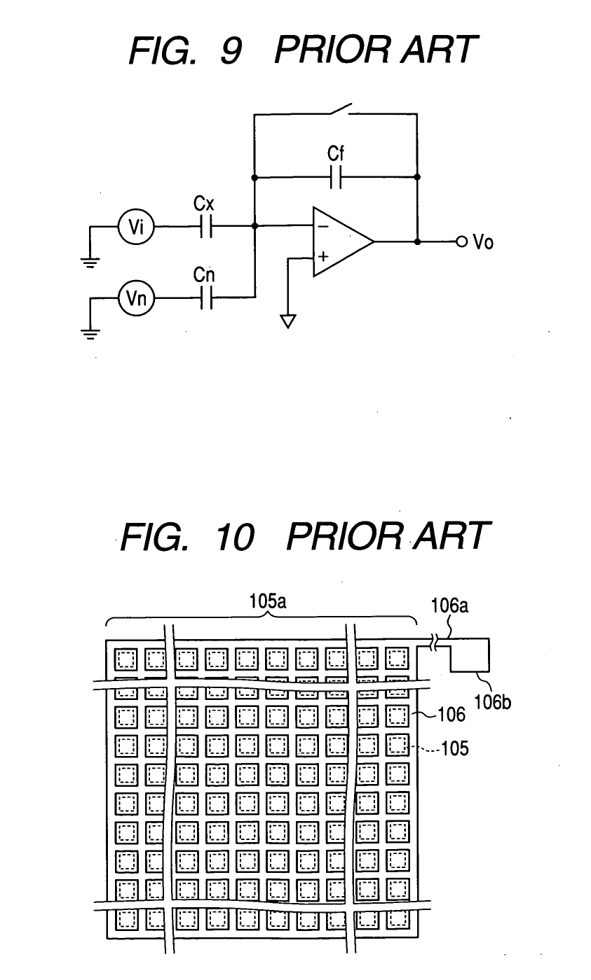

That is, a charge amplifier circuit 31 preferably has a configuration as shown in FIG. 7 from a viewpoint of a countermeasure against erroneous operations at the time of setting operation points or when the reference electrode is opened.

In FIG. 7, as described in the first embodiment, the switch 1 it turned on before the start of the measurement to discharge the electric charges stored in the capacitance Cf.

Further, when the detection of the unevenness of the subject to be measured is not performed, a switch SW3 is turned off and a switch SW2 is turned on at the same timing as that of the switch SW1. Then, the non-inversion terminal (+) is set to Vp as an operation reference potential and the electric charges of the capacitances Cf, Cx, and Cn are discharged (reset), such that the output voltage of the inversion terminal (−) is set to a predetermined DC voltage Vp.

Then, when the measurement of the unevenness of the subject to be measured is performed, the switches SW1 and SW2 are turned off and the switch SW3 is turned on. Accordingly, the charge amplifier circuit 11 operates in a state in which the reference voltage (the noise voltage) is superimposed on the predetermined DC voltage Vp in the non-inversion terminal.

As such, when the operation is started, the voltages on the inversion terminal and the non-inversion terminal are set to the same DC voltage Vp, which serves as the reference of the displacement voltage.

### Fourth Embodiment

FIG. 8 shows a configuration in which a ground electrode 3 and a reference electrode 2 are alternately arranged in comb-teeth shapes with respect to the detection electrodes 1 in a portion where the ground electrode 3 is spread all over in FIG. 1.

That is, the reference electrode 2 and the ground electrode 3 are formed in the comb-teeth shapes and tooth electrodes in a longitudinal direction of the comb-teeth shapes thereof are alternately arranged. The detection electrodes 1 are arranged in a single line (or plural lines) between the tooth electrodes of the reference electrode 2 and the ground electrode 3. The detection electrodes 1 are provided at a predetermined pitch in series between the reference electrode 2 and the ground electrode 3, that is, the tooth electrodes of the comb-teeth shapes of the reference electrode 2 and the ground electrode 3.

Specifically, one tooth electrode of the comb-teeth shape of the reference electrode 2 is arranged at one side of the column of the detection electrodes 1 and one tooth electrode of the comb-teeth shape of the ground electrode 3 is arranged at the other side of the column.

As such, the reference electrode 2 and the ground electrode 3 can be arranged near the detection electrodes 1, and thus the noise can be absorbed by the neighboring ground electrode 3. Further, precision of monitoring a potential level of the human body through the reference electrode 2 can be advanced. As a result, the noise components can be more effectively removed.

Further, in the invention, the configuration in which the difference between the reference voltage and the measurement voltage is used as the measurement result can be applied to other capacitance detection-type sensors, in addition to the capacitance detection-type sensor having the above-described configuration.

As described above, in the capacitance detection-type sensor of the invention, the voltage by the noise inputted from the subject to be detected is set to the reference voltage and is subtracted from the detected detection voltage. Then, the subtraction result is set to a substantial detection value. Thus, even when the sensitivity of the charge amplifier circuit is increased, the unevenness of the subject to be detected can be detected with high precision with no saturation.

1. A capacitance detection-type sensor which detects an electrostatic capacitance between a subject to be detected and a detection electrode arranged on a surface of the sensor and detects the shape of the subject to be detected, the capacitance detection-type sensor comprising:
a reference electrode that is arranged near the detection electrode and detects a potential of the subject to be detected; and
a potential detecting section that measures a detection potential based on the electrostatic capacitance of the detection electrode with the potential as a reference potential.

2. The capacitance detection-type sensor according to claim 1,
wherein row wiring lines and column wiring lines are formed on a substrate in a matrix shape and a change in capacitance between both wiring lines at each of intersections of the row wiring lines and the column wiring lines is detected.

3. The capacitance detection-type sensor according to claim 1,
wherein a ground electrode is arranged near the detection electrode.

4. The capacitance detection-type sensor according to claim 2,
wherein the potential detecting section acquires the difference between the detection potential by the detection electrode that detects the potential of the subject to be detected and a detection potential of another detection electrode adjacent to the detection electrode and outputs the difference as a detection potential of the measurement result.

5. The capacitance detection-type sensor according to claim 3,
wherein the reference electrode and the ground electrode are formed in comb-teeth shapes and the detection electrode is formed between the teeth of the reference electrode and the ground electrode.
